(19) United States
(12) Patent Application Publication
(10) Pub. No.: US 2005/0102600 A1
(43) Pub. Date: May 12, 2005

(54) High data rate communication system for wireless applications

(76) Inventor: Anand Anandakumar, San Diego, CA (US)

Correspondence Address: DAVID A. HALL, HELLER EHRMAN ET AL., 4350 LA JOLLA VILLAGE DRIVE #700, SAN DIEGO, CA, 92122, US

(21) Appl. No.: 10/705,597

(22) Filed: Nov. 10, 2003

(51) Int. Cl. H03M 13/00; H03M 13/03

(52) U.S. Cl. 714/755

(57) ABSTRACT

A decoder for a communication system includes an iterative decoding module configured to receive soft-input information bits. The iterative decoding module iterates on probability estimates of the soft-input information bits to generate hard-decision output information. The iterative decoding module includes a plurality of arithmetic modules operating to generate and process both backward and forward metrics substantially simultaneously using modulo arithmetic operations.

### BACKGROUND

1. Field

The present invention relates generally to wireless communication systems and, more particularly, to high data rate wireless applications.

2. Description of the Related Art

Fourth generation (4G) wireless applications will require more advanced error correcting techniques than previous wireless applications. The 4G error correcting techniques will enable reliable data transmission and greater data rates at lower channel signal-to-noise ratio (SNR). A class of forward error correction codes, referred to as turbo codes, offers significant coding gain for power-limited communication channels. Turbo codes are generated by using two or more recursive systematic convolutional (RSC) encoders operating on different orderings of the same information bits. A subset of the code bits generated by each encoder is transmitted to maintain bandwidth efficiency. Turbo decoding involves an iterative technique in which probability estimates of the information bits that are derived for one of the decoded code words are fed back to a probability estimator for a second one of the code words. Each iteration of processing generally increases the reliability of the probability estimates. This process continues, alternately decoding the two code words until the probability estimates are sufficient to make reliable decisions about the original information bits.

Prior to turbo codes, the commonly used error correcting codes were convolutional encoders paired with Viterbi decoders. Convolutional codes are capable of allowing a communication system to reach the Shannon limit, which is the theoretical limit of SNR for error free communication over a given noisy channel. Viterbi decoders, however, grow exponentially in complexity as their error correction capability is increased, making their practical limit 3 dB to 6 dB away from the Shannon limit for practical hardware/software implementations. In contrast to convolutional codes, turbo codes implemented with a practical decoder have been shown to achieve a performance of 0.7 dB from the Shannon limit, far surpassing the performance of a convolutional-encoder/Viterbi-decoder of similar complexity. Turbo decoding techniques have not yet reached the maturity and open availability that Viterbi techniques enjoy, so implementing a turbo code is not a trivial exercise. A 3G standard written by an industry group called the Third Generation Partnership Project (3GPP) specifies the design of the turbo encoder in great detail but does not specify the decoder design, leaving that choice up to the designer.

A maximum a posteriori (MAP) decoding technique introduced by Bahl, Cocke, Jelinick, and Raviv in “Optimal Decoding of Linear Codes for Minimizing Symbol Error Rate”, IEEE Transactions on Information Theory, March 1974, pp. 284-287, is a symbol-by-symbol decoder for trellis codes. The MAP technique delivers excellent performance as a component decoder in decoding turbo codes. The technique is advantageous for decoding turbo codes because it accepts soft-decision information as an input and produces soft-decision output information.

The MAP technique can be used in a turbo decoder to generate a posteriori probability estimates of the systematic bits (i.e., information bits) in a first iteration of decoding the code word. These probability estimates are used as a priori symbol probabilities in a second iteration. Those skilled in the art will recognize three fundamental terms in descriptions of the MAP technique, which are: forward and backward state probability functions (the alpha and beta functions, respectively) and the a posteriori transition probabilities (the sigma function).

One problem with the MAP technique for the turbo decoder is that a relatively large amount of memory is required. For example, the entire received code word must be stored during decoding due to the nature of the MAP technique. Furthermore, in order to obtain high-speed decoding, it is necessary to store a large number of intermediate results that represent various event probabilities of interest so they can be combined with other results later in the decoding process. The MAP technique as described by Bahl et al. requires that at least half of the results from the two recursive calculations be stored in memory for fast decoding. Such requirements can limit the decoding computation speed and can tax system memory resources.

Therefore, it is desirable to reduce the time for computation and memory required in turbo decoding without compromising coding gain. Thus, there is a need for improved turbo decoder design. The present invention satisfies this need.

### SUMMARY

A decoder for a communication system includes first and second decoder blocks and a decision module. The first decoder block calculates a probability estimate for each soft-input information bit. The second decoder block receives and processes the probability estimate of the soft-input information bits using modulo arithmetic operations. The decision module receives the processed soft-input information bits and generates hard-decision output information.

In another aspect, a decoder for a communication system includes an iterative decoding module configured to receive soft-input information bits. The iterative decoding module iterates on probability estimates of the soft-input information bits to generate hard-decision output information. The iterative decoding module includes a plurality of arithmetic modules that generate and process both backward and forward metrics substantially simultaneously using modulo arithmetic operations.

In another aspect, a decoder for a communication system can include a soft-input soft-output (SISO) decoding module. The SISO decoding module includes a first plurality of modules to receive and process soft-input backward state metrics using modulo arithmetic. The module also includes a second plurality of modules to receive and process soft-input forward state metrics using modulo arithmetic.

In another aspect, a decoding method is applied to soft-input information bits with a backward recursion that is performed using a trellis diagram by computing backward state metrics of each node on the trellis diagram of the symbol information bits. The backward state metrics are stored in a storage mechanism. A forward recursion is then performed on the trellis diagram by computing forward state metrics of each node on the trellis diagram of the symbol block data. Finally, the extrinsic information is calculated.

Other features and advantages of the present invention should be apparent from the following description of the preferred embodiment, which illustrates, by way of example, the principles of the invention.

### BRIEF DESCRIPTION OF THE DRAWINGS

FIG. 1 is a block diagram of a wireless communication system in which exemplary embodiments of the invention can be practiced.

FIG. 2 is a block diagram of the transmitter system shown in FIG. 1.

FIG. 3 is a block diagram of an exemplary transmitter system configured as a particular embodiment of the transmitter system in FIG. 2.

FIG. 4 is a functional block diagram of the turbo encoder shown in FIG. 3.

FIG. 5 is a block diagram of the receiver system shown in FIG. 1.

FIG. 6 is a detailed block diagram of the exemplary receiver system illustrated in FIG. 5.

FIG. 7 is a functional block diagram of the turbo decoder shown in FIG. 6.

FIG. 8 shows a trellis diagram with eight states in the vertical axis, and k+3 time intervals along the horizontal axis.

FIG. 9 is a flowchart that illustrates the computations performed by the exemplary MAP decoders of FIG. 7.

FIG. 10 illustrates an exemplary parallel window technique in which the decoder of FIG. 5 divides a data symbol block into a predetermined number of windows.

FIG. 11 illustrates an example of a memory storage reduction technique used by the FIG. 7 decoders that reduces the storage requirements for the backward state metrics.

FIG. 12 shows an alternative example of the memory storage reduction technique for storing the backward state metrics of a MAP decoder.

FIG. 13 shows an exemplary interleaving process implemented by the decoder of FIG. 5.

FIG. 14 is a block diagram of a MAP decoder shown in FIG. 7.

### DETAILED DESCRIPTION

Exemplary embodiments are described for a communication system having a transmitter and a receiver such that the receiver includes an efficient, high data-rate turbo decoder for wireless applications. The high data-rate turbo decoder implements mathematical and approximation techniques that significantly reduce the required computations and the need for memory storage. In particular, the turbo decoder uses modulo arithmetic in maximum a posteriori probability (MAP) modules configured with double add-compare-select (ACS) circuits. The MAP modules use a parallel window technique to perform backward state metric calculation recursion and to store the metrics. Forward state metric calculation and the probability estimate (referred to as extrinsic information) calculation are performed in parallel using the stored backward state metrics. These techniques increase the speed of computation and reduce the memory required for computation.

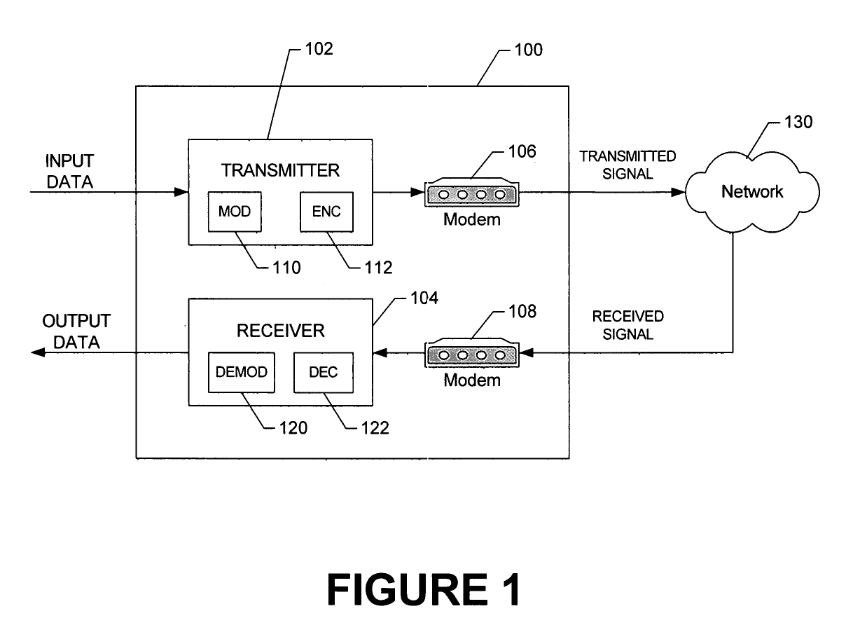

FIG. 1 is a block diagram of a wireless communication system 100 in which exemplary embodiments of the invention can be practiced. The communication system 100 includes a transmitter system 102 and a receiver system 104, which communicate with each other over a network 130 through modems 106, 108, respectively. The modems 106, 108 can transmit and receive signals and/or share resources through the network 130, which can comprise a local area network (LAN), a wide area network (WAN) (e.g., the Internet), or a code division multiple access (CDMA) telecommunications network. The local area network (LAN) can be configured as a home or office wireless network designed to communicate and share data and resources between devices, particularly at a high data rate. Thus, in one embodiment, the modems 106, 108 can operate in a high frequency (e.g., 3 to 10 GHz) region with a relatively wide bandwidth (e.g., up to 7 GHz). Furthermore, the modems can operate over the operating bandwidth in a multicarrier configuration.

The transmitter 102 and receiver 104 of the communication system 100 can be configured as a handheld mobile unit such as a personal digital assistant (PDA), or can be configured as a mobile station telephone, a base station, or other systems/devices that generate and receive digital signals for transmission. The transmitter 102 and receiver 104 can be implemented in a single device that provides a transceiver. The modulator 110 and the encoder 112 in the transmitter system 102, and the demodulator 120 and the decoder 122 in the receiver system 104, include decoders comprising different embodiments as described in detail below.

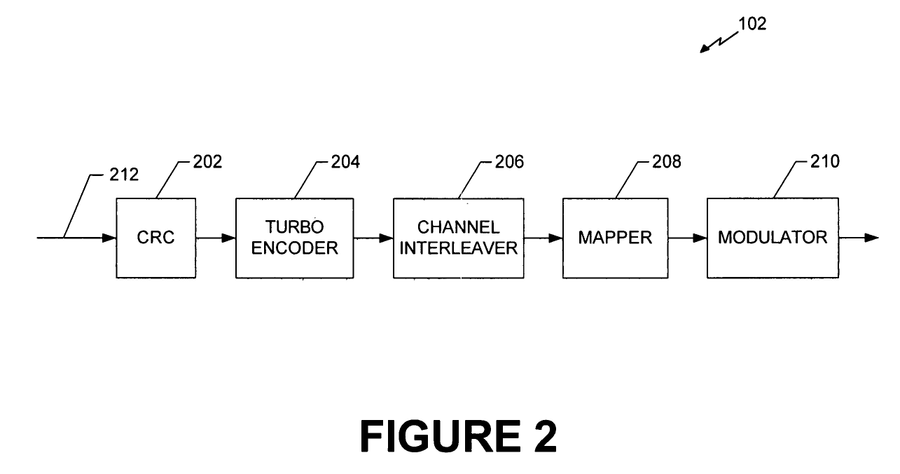

FIG. 2 is a block diagram of a transmitter system 102 configured in accordance with the present invention. Input data 212 is sent to a cyclic redundancy check (CRC) generator 202 that generates CRC checksum data for a predetermined amount of data received. The input data and checksum data comprise a resulting data block. The resulting data blocks are sent to a turbo encoder 204, which processes the data block and generates code symbols that are supplied to a channel interleaver 206. The code symbols typically include a retransmission of the original input data (called the systematic symbol), and one or more parity symbols.

The number of parity symbols transmitted for each systematic symbol depends on the coding rate of the transmission. For a coding rate of one-half (½), one parity symbol is transmitted for every systematic symbol, for a total of two symbols generated for each data bit (including CRC) received. For a one-third rate (⅓) turbo coding rate, two parity symbols are generated for each systematic symbol, for a total of three symbols generated for each data bit received.

The code symbols from the turbo encoder 204 are sent to a channel interleaver 206, which interleaves the symbol blocks as they are received. Typically, the channel interleaver 206 performs block or bit-reversal interleaving. Other types of interleavers may be used as the channel interleaver 206, so long as the code symbols are interleaved.

A mapper 208 takes the interleaved code symbols from the channel interleaver 206 and generates symbol words of predetermined bit width based on a mapping scheme. The mapping scheme is described further below. The symbol words are then applied to a modulator 210 that generates a modulated wave form based on the symbol word received. Typical mapping techniques include BPSK, QPSK, 8-PSK, 16 QAM, and 64 QAM. Typical modulation techniques include single carrier modulation, and multi carrier modulation. Various other modulation schemes can be utilized. The modulated waveform is then upconverted for transmission at an RF frequency.

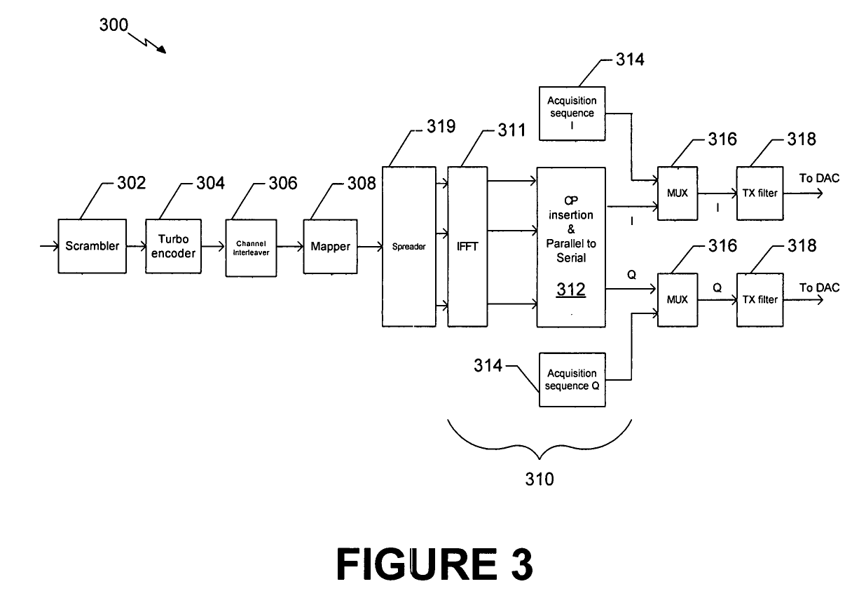

FIG. 3 is a block diagram of an exemplary transmitter system 300 configured as a particular embodiment of the transmitter system 102 illustrated in FIG. 2. The exemplary transmitter system 300 is configured as a multicarrier-spread spectrum (MC-SS) system, where a communication path having a fixed bandwidth is divided into a number of sub-bands having different frequencies. The width of the sub-bands is chosen to be small enough to allow the distortion in each sub-band to be modeled by a single attenuation and phase shift for the band. If the noise level in each band is known, the volume of data sent in each band can be optimized by choosing a symbol set having the maximum number of symbols consistent with the available signal to noise ratio of the channel. By using each sub-band at its maximum capacity, the amount of data that can be transmitted in the communication path is maximized.

Multicarrier transmission schemes, such as Orthogonal Frequency Division Multiplexing (OFDM), have been proposed and are used for many different types of communication systems, including broadband wireless Local Area Networks (LANs). The advantage of such schemes is that highly time dispersive channels can be equalized efficiently to provide transmission data rates that, when combined with forward error correction techniques, are capable of approaching the theoretical Shannon limit for a noisy channel. A highly dispersive channel can arise from a combination of multiple discrete, delayed, and attenuated signals, particularly in radio frequency environments, or can be an intrinsic property of a transmission medium (such as within a wireline copper-pair or a fiber-optic transmission system) where the group delay is a continuous function of frequency. Additionally, these types of multicarrier systems are particularly suited to wide bandwidth applications having high data rates.

The transmitter system 300 includes a turbo encoder 304, an interleaver 306, a mapper 308, a spreader 319, and a multicarrier modulator 310, similar to the corresponding modules of the system 102 (FIG. 2). The exemplary transmitter system 300 further includes a scrambler 302 for data security. In one embodiment, the scrambler 302 can also perform the function of the CRC generator 202 (FIG. 2). The modulator 310 is implemented with banks of digital filters 311 that make use of inverse fast Fourier transforms (IFFT) and includes modules 312, 314 for data acquisition. The system 300 also includes modules 316, 318 for data transmission.

In the particular embodiment of FIG. 3, a single data stream to be transmitted over the communication path can be broken into a plurality of N sub-bands. Each sub-band is transmitted during a system communication cycle. During each communication cycle, the portion of the data stream to be transmitted is converted to N symbols chosen to match the capacity of the various N sub-band channels. Each symbol represents the amplitude of a corresponding sub-carrier. The time domain signal to be sent on the communication path is obtained by modulating each sub-carrier by its corresponding amplitude and then adding the modulated carriers to form the signal to be placed in the communication path. This operation is carried out by transforming a vector of N symbols using the IFFT filter 311 to generate N time domain values that are sent in sequence on the communication path. At the receiver end of the communication path, the N time domain values can be accumulated and transformed using a fast Fourier transform to recover the original N symbols after equalization of the transformed data to correct for the attenuation and phase shifts that occurred in the channels.

For channels with memory, such as fading channels, errors typically come in bursts, rather than being randomly distributed. The interleaver 306 is used to reorder a binary sequence in a systematic way to disperse the burst errors, making them easier to correct.

The spreader 319 spreads the symbol word over multiple sub-carriers to achieve frequency diversity. The sub-carrier distance and the number of sub-carriers are appropriately chosen so that it is unlikely that the symbol word is completely located in a deep fade. This system is referred to as a multicarrier-spread spectrum (MC-SS) system.

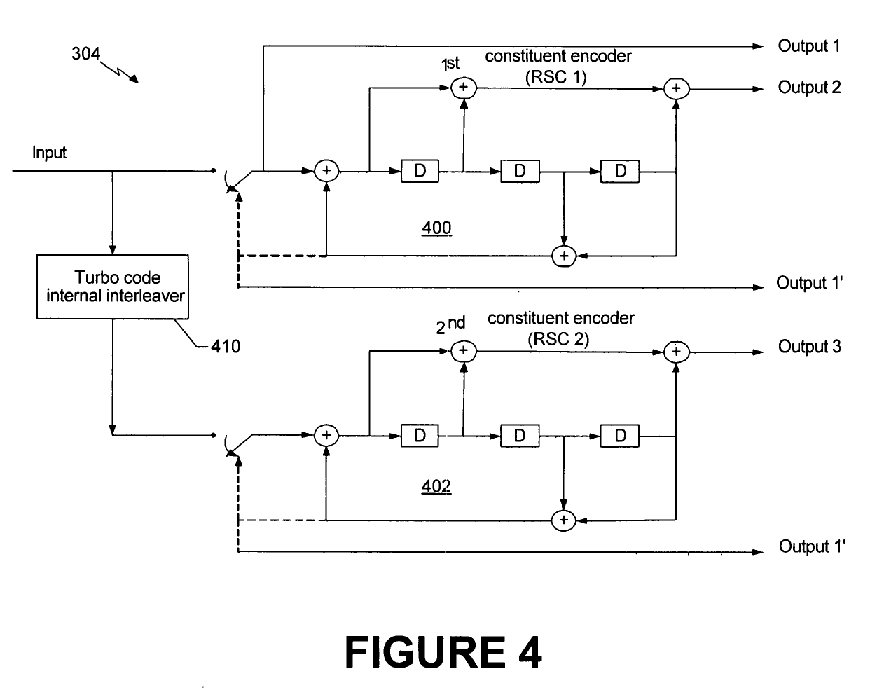

FIG. 4 is a functional block diagram of a turbo encoder 304 constructed according to the invention. In the illustrated embodiment of FIG. 4, the encoder 304 includes two 8-state convolutional encoders (i.e., the “constituent” encoders) 400, 402. Each convolutional encoder includes a plurality of delay elements (indicated by blocks with D designations) that generate polynomial terms used in convolutional equations.

The data bit stream from the scrambler 302 (FIG. 3) is received as input and enters the first constituent encoder 400 that produces a parity bit (Output 2) for each input bit. The input data bit stream also goes through an interleaver 410, which scrambles the bit ordering, and then goes to the second constituent encoder 402, which produces a parity bit (Output 3) for each input bit. The bit ordering of the interleaver remains the same from frame to frame. For the 3GPP standard, the interleaver 410 operates on a data frame length that can be in a range from 40 bits to 5114 bits long. The data sent across the channel is the original bit stream (Output 1), the parity bits (Output 2) of the first constituent encoder 400, and the parity bits (Output 3) of the second constituent encoder 402. Thus, the turbo encoder 304 is a rate ⅓ encoder.

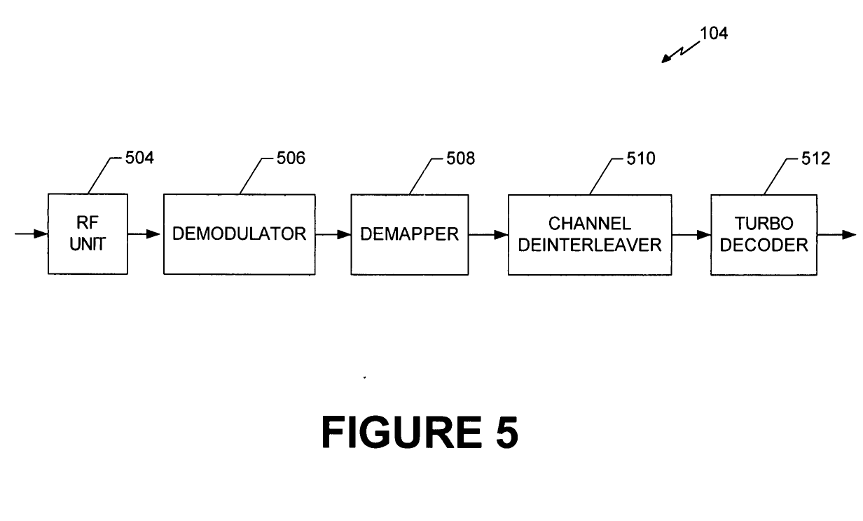

FIG. 5 is a block diagram of a receiver system 104 configured in accordance with the invention. The receiver system 104 includes an RF unit 504 that receives, acquires, down-converts, and filters input RF signals. A demodulator 506 then demodulates, processes, and digitizes the down-converted signals. A demapper 508 receives the digitized data and provides soft decision data to a channel deinterleaver 510. The turbo decoder 512 decodes the soft decision data from the channel deinterleaver 510 and supplies the resulting hard decision data to a processor or control unit of the receiver system 104, which can check the accuracy of the data using the CRC checksum data.

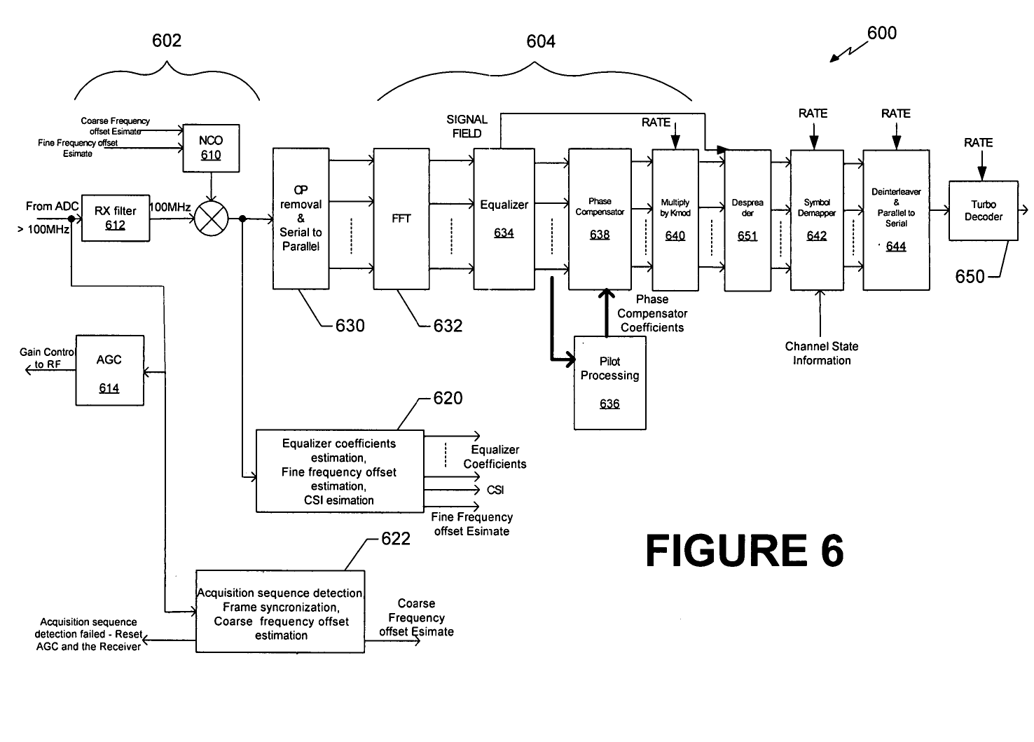

FIG. 6 is a block diagram of an exemplary receiver system 600 configured as a particular embodiment of the receiver system 104 shown in FIG. 5. The receiver system 600 includes an RF unit 602, a demodulator 604, a symbol demapper 642, a channel deinterleaver 644, and a turbo decoder 650, similar to the corresponding modules of the receiver system 104 illustrated in FIG. 5. However, the exemplary receiver system 600 includes additional modules 620, 622, 630 used for data acquisition and conversion.

In the particular embodiment of FIG. 6, the RF unit 602 includes a numerically controlled oscillator (NCO) 610, a receive filter 612, and an automatic gain control (AGC) module 614. The demodulator 604 is implemented as a multicarrier-spread spectrum demodulator using a fast Fourier transform (FFT) module 632. The demodulator 604 also includes an equalizer 634, a pilot processing module 636, phase compensator 638, a multiplier 640, and a despreader 651. The processing of the modules will be understood by those skilled in the art.

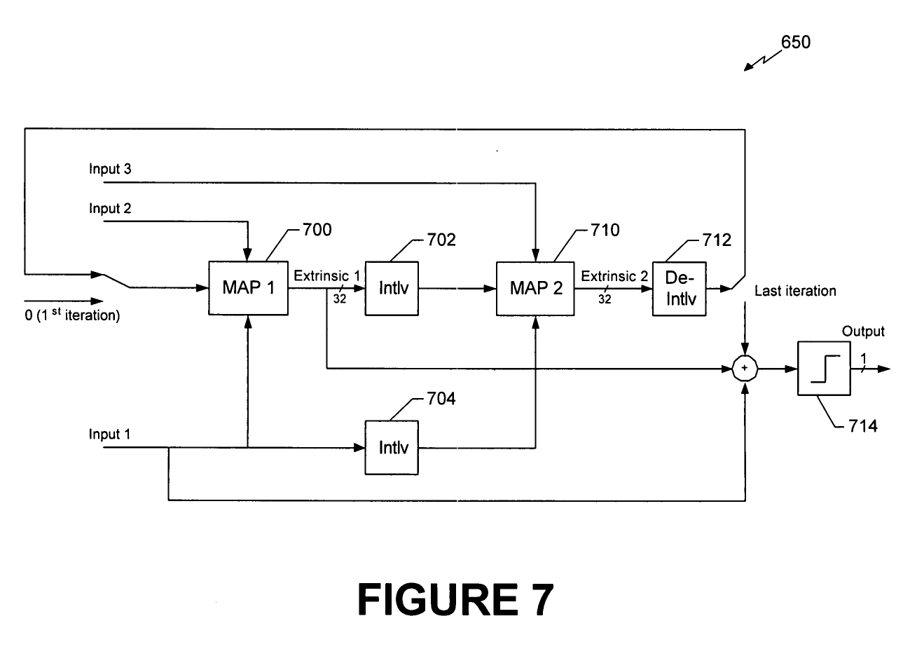

FIG. 7 is a functional block diagram of a high data-rate turbo decoder 650 according to an embodiment of the invention. Because a pure maximum likelihood decoder for a turbo code is very complex to implement, the exemplary decoder 650 employs an iterative decoding scheme to approximate the maximum likelihood computation, thereby conserving memory resources and increasing computation speed.

The high data-rate turbo decoder 650 operates in an iterative fashion with two decoder blocks 700, 710 corresponding to the two constituent encoders 400, 402 (see FIG. 4). The first decoder block 700 (MAP1) makes an estimate of the probability for each data bit as to whether it is a 1 or a 0 by operating on the received data (Input 1 in FIG. 7 corresponding to Output 1 in FIG. 4) and parity bits (Input 2 in FIG. 7 corresponding to Output 2 in FIG. 4) that were produced by the first constituent encoder 400. The received data and parity bits are soft values from the channel deinterleaver. The estimate of the probability (Extrinsic 1) is then sent to the second decoder block 710 (MAP2), through an interleaver 702, along with the interleaved received data and the parity bits (Input 3) produced by the second constituent encoder 402. The received data (Input 1) is interleaved by an interleaver 704 and provided to the second decoder block.

The above-described process of two passes through the decoding technique from MAP1 to MAP2 is considered to be one iteration of the decoder 650 and is repeated for a fixed number of iterations, or until some external mechanism determines that no further iterations will improve the bit error rate (BER) for that frame. For example, the external mechanism can comprise processing that detects when a sequence of estimations has not changed below an error threshold value. That is, if the change from one iteration to the next is below the error threshold, then the iterations are complete. After all iterations are complete, the original data bits are recovered by making a hard decision on the last soft output. The hard decision is made by a decision module 714. The bit output is then produced by the decision module 714.

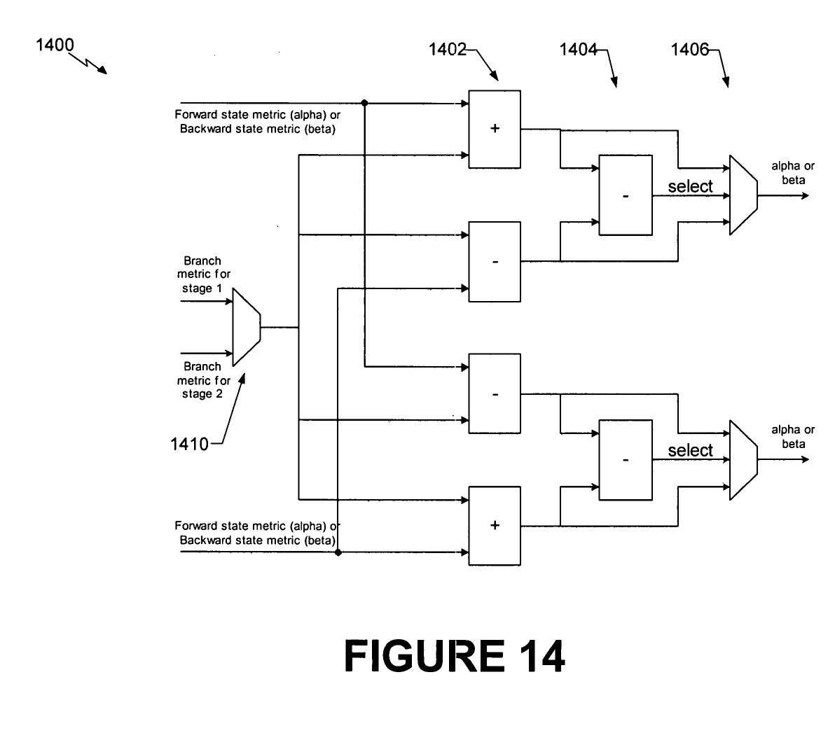

The decoding technique employed within the two decoder blocks 700, 710 operates on soft inputs (the deinterleaver outputs and the probability estimates) and produces soft outputs. A high data-rate Maximum a posteriori Probability (MAP) decoder (see FIG. 14 for detail) produces good BER performance for these requirements. Although the illustration in FIG. 7 shows two MAP decoders, in the preferred embodiment they are physically implemented as one unitary MAP decoder. Those skilled in the art will understand how to implement a single MAP decoder to function as the structure illustrated in FIG. 7, by operating as MAP 1 during one cycle and then as MAP2 during another cycle.

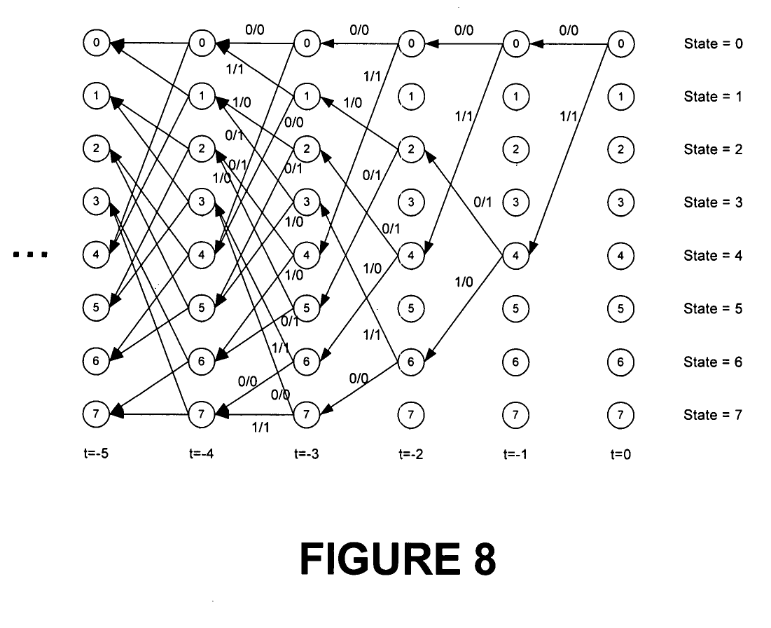

The unitary MAP decoder is configured as a trellis decoder, like the Viterbi decoder. Accordingly, each constituent trellis encoder in the turbo encoder can be defined by a trellis diagram with eight states in the vertical axis, and k+3 time intervals along the horizontal axis as shown in FIG. 8. The term k is the length of the interleaver and the three extra time intervals are needed for the trellis termination (getting the encoder back to state 0). The trellis diagram is simply a state diagram with a time axis. After three time intervals the branches in the trellis repeat themselves, so only one time slice of the trellis is needed to define the entire trellis.

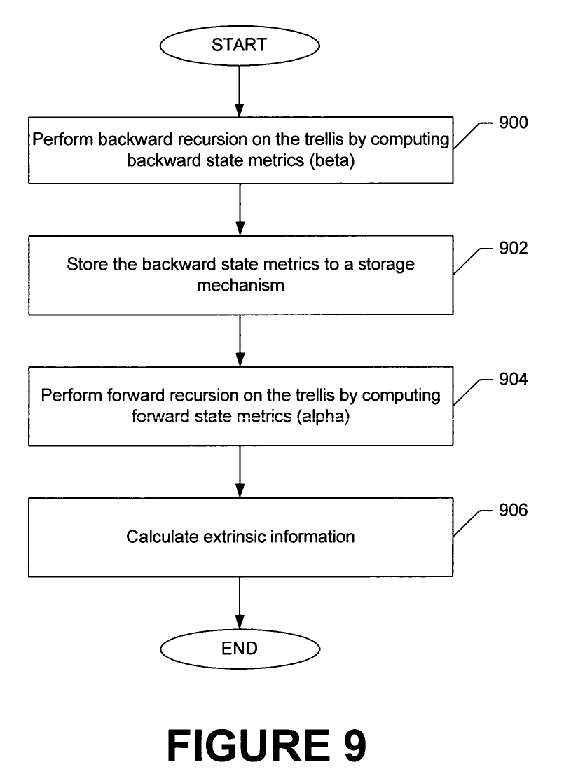

The computation operations for an exemplary embodiment of a decoding technique for a modified unitary MAP decoder are summarized in a flowchart shown in FIG. 9. The illustrated computation correspond to one iteration of one MAP decoder in the functional block diagram of FIG. 7.

Initially, at the first box 900, a backward recursion is performed on the trellis by computing backward state metrics (i.e., beta values) for each node in the trellis diagram. The backward state metric of a node is the sum of the previous backward state metric (i.e., at the previous time point) multiplied by the branch metric along each branch from the two previous nodes to the current node. The branch metric (gamma value) is the exponential of the trellis distance between the hard encoder values and the soft received values from the deinterleaver, divided by the channel noise variance, multiplied by the probability estimate from the previous decoder. The computation starts at the end of the trellis diagram and progresses in the reverse direction. At box 902, the backward state metrics are stored in a storage mechanism such as a random access memory (RAM). Various techniques for reducing the storage requirement for the backward state metrics are discussed in detail below.

A forward recursion on the trellis is performed at box 904 by computing the forward state metrics (i.e., alpha values) for each node in the trellis diagram. The forward state metrics can be computed in a similar manner as the backward state metrics. For the forward state metrics, however, the computation starts at the beginning of the trellis diagram and progresses in the forward direction.

Extrinsic information that is to be delivered to the next decoder in the iteration sequence is computed at box 906. Computation of the extrinsic information involves computing the log likelihood ratio (LLR) for each time point. The LLR value is computed as the sum of the products of the alpha, beta, and gamma values for each branch at a particular time that is associated with a ‘1’ in the encoder, divided by the sum of the products of the alpha, beta, and gamma values for each branch at the same particular time that is associated with a ‘0’ in the encoder. Finally, the extrinsic information is the LLR value minus the input probability estimate.

This sequence of computations is repeated for each iteration by each of the two decoders MAP1 and MAP2. After all iterations are completed, the decoded information bits can be retrieved by examining the sign bit of the LLR value. If the sign bit is positive, then the resultant bit is a one. If the sign bit is negative, then the resultant bit is a zero. This is because the LLR value is defined to be the logarithm of the ratio of the probability that the bit is a one to the probability that the bit is a zero.

Since the conventional MAP design is relatively complex, with computations involving exponentials, a real-time operation of the MAP decoder is usually difficult and better to avoid. Therefore, some simplifications and approximations can be used to significantly reduce the required computations and provide greater efficiencies. For example, the computations of the MAP decoder technique can be configured to operate in the log domain. This converts all multiplications to additions, divisions to subtractions, and eliminates exponential and log computations, without affecting the bit error rate (BER) performance. Operating in the log domain also keeps growth of the state metric numbers to a manageable range. In practice, since the log of the sums of exponentials are frequently needed, an additional simplification is used in the preferred embodiment. The simplification involves using the Jacobian formula to simplify the log of the sums of exponentials as max-log. Accordingly, a MAP decoder can be implemented as a max-log-MAP decoder without significantly affecting the BER performance.

In another exemplary simplification, modulo arithmetic computation is used to obviate the need for scaling and/or normalization. Because the backward and forward recursions require successive multiplications by numbers less than one, even 32-bit floating-point numbers will underflow unless they are scaled. Scaling requires additional operations that will slow down the turbo decoder. By using the log domain and the modulo arithmetic computation, no scaling may be needed for 32-bit fixed-point numbers. Exemplary computer programs (written in C language) that can be performed by the MAP decoder for the modulo arithmetic are shown in the Appendix (below). The programs can be implemented by having an 11-bit register and allowing the result of the arithmetic operation to wrap around or overflow. The Appendix also includes examples of computer programs illustrating the computation techniques for calculating the backward state metrics, the forward state metrics, and the extrinsic information.

As mentioned above, the backward state metrics should be stored because all the previous backward state metrics are needed to compute the current state metrics and the external information. This results in a storage requirement for a large number of state metrics, which leads to an unacceptable cost for most practical interleaver sizes. In accordance with the preferred embodiment, one of the solutions to the storage problem is the introduction of the aforementioned parallel window technique.

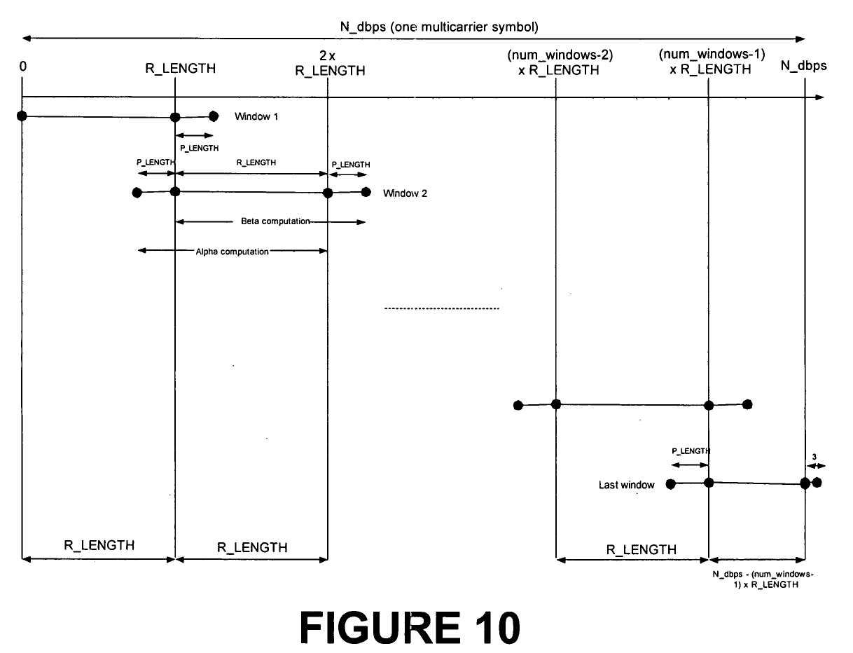

FIG. 10 illustrates an exemplary parallel window technique in which a data symbol block (N_dbps, which represents one multicarrier symbol) is divided into a predetermined number of windows (num_windows). In the illustrated embodiment of FIG. 10, the data symbol block includes 2506 data bits with 128 bits per window. This results in nineteen windows with 128 bits and one window with 74 bits. Moreover, since the data bits are interdependent, parallel windows are configured to overlap. In the illustrated embodiment of FIG. 10, the range of the overlapping is set at 30 bits. However, the size of the window and the range of the overlapping can be adjusted to provide the best result.

The backward state metric in the parallel window technique is now initialized at the end of the window rather than at the end of the symbol block. The forward state metric is initialized at the beginning of the window. In practice, the computations of the state metrics overlap into the subsequent/previous windows. The computation of the backward and forward state metrics in the parallel windows are performed in parallel. Accordingly, the size of the backward state metrics to be stored is significantly reduced.

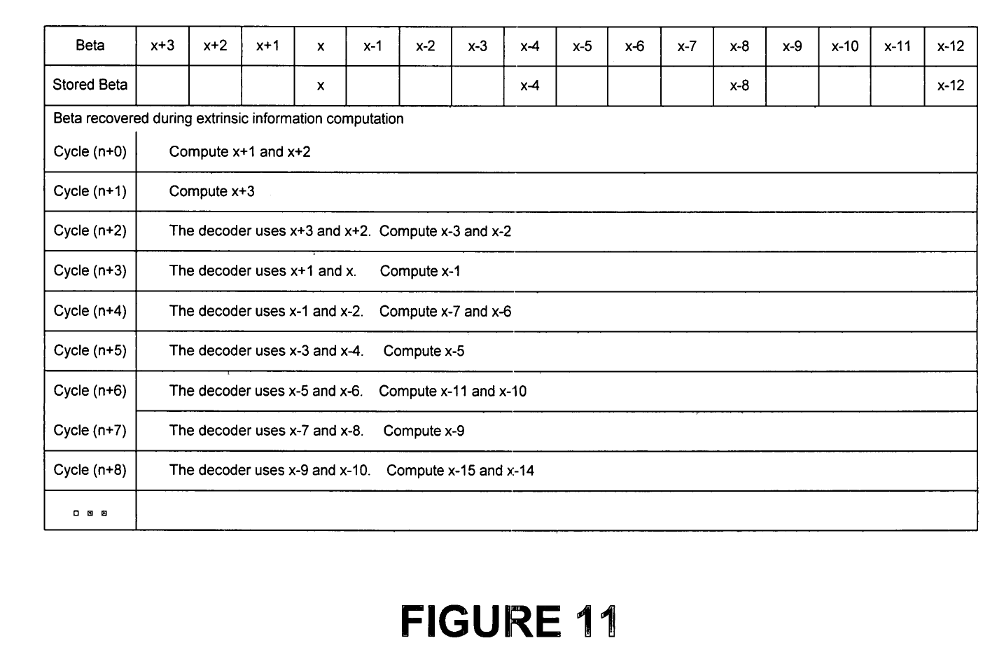

FIG. 11 shows an example of a memory storage reduction technique for further reducing the storage requirements for the backward state metrics of a high data-rate MAP decoder. The technique involves storing only a fraction of the state metrics into a memory. In the illustrated embodiment of FIG. 11, only every third metric is stored. The missing metrics are recalculated when they are needed during the computation of the extrinsic information. It has been found that this reduces the memory requirement by approximately 75%.

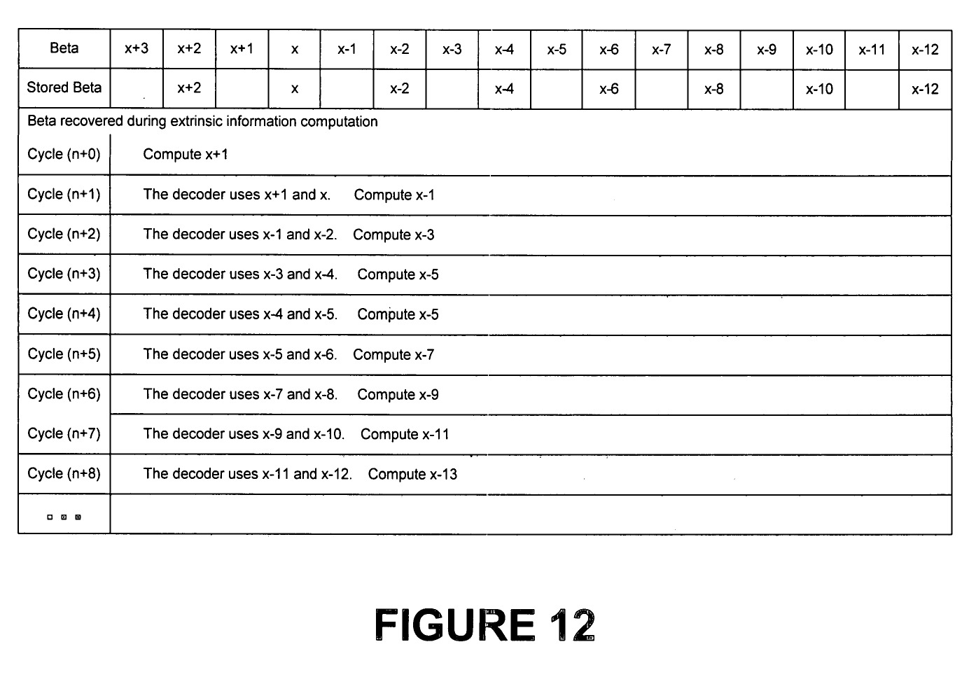

FIG. 12 shows an alternative example of the memory storage reduction technique for storing the backward state metrics of a modified unitary MAP decoder. In the illustrated embodiment of FIG. 12, only every other metric is stored. The missing metrics are recalculated when they are needed during the computation of the extrinsic information. It has been found that this reduces the memory requirement by approximately 50%.

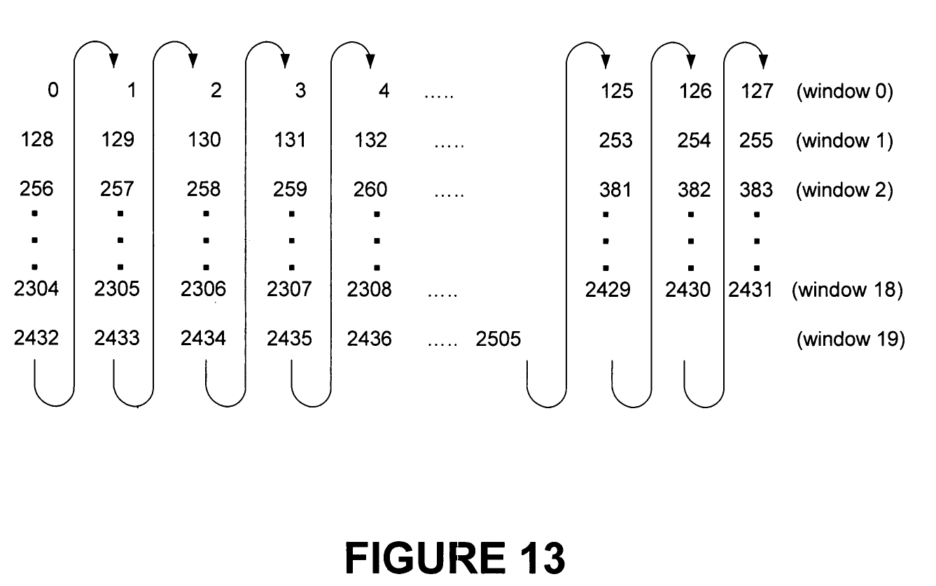

Once the symbol block has been divided into parallel windows, the data bits for each window can be interleaved as illustrated in FIG. 13. In the interleaving process of FIG. 13, the data bits are arranged in a parallel window configuration and written in a row-wise format, but are read in a column-wise format. Therefore, the bit sequence 0, 1, 2, 3, . . . 2505 is interleaved to transmit at another bit sequence as 0, 128, 256, . . . , 2304, 2432, 1, 129, 257, . . . , 2305, 2433, 2, 130, . . . , 2431.

Since the last window has a different number of bits from other windows, the interleaving process is somewhat awkward and asymmetrical. To simplify the interleaving process, the last window can be separated from the rest of the windows. Thus, the interleaving process for the windows 0 through 18 becomes rectangular block interleaving. The last window can be interleaved independently and appended to the result of the rectangular block interleaving of the first 19 windows. The resultant interleaved bit sequence is 0, 128, 256, . . . , 2304, 1, 129, 257, . . . , 2305, 2, 130, . . . , 2431, 2432, 2451, . . . , 2505.

FIG. 14 is a block diagram of a high data-rate MAP decoder 1400 constructed in accordance with an embodiment of the invention. In the embodiment of FIG. 14, each trellis stage of the MAP decoder 1400 includes eight states (memory=3). Thus, eight decoders will be required to process the eight states. Two states of a trellis stage are implemented in a double-ACS configuration. The term “ACS” refers to the order of the computations (add, compare, and select) performed in the decoder. All of the computations are performed using the aforementioned modulo arithmetic. The modified MAP decoder 1400 of the illustrated embodiment shown in FIG. 14 is a type of soft-input soft-output (SISO) decoder/module.

The double-ACS based decoder 1400 is used for two trellis stages in each cycle, performing the first stage during the rising edge of a clock cycle and performing the second stage during the falling edge of a clock cycle. A multiplexer 1410 receives and selects appropriate branch metrics for a particular stage. The modules 1402 perform modulo-add and modulo-subtract to process branch metrics and forward or backward state metrics. The results of the modulo arithmetic are compared in the modulo-subtract modules 1404 to perform the MAX function. As described above, the MAX function approximates the log of exponentials. The multiplexers 1406 select backward or forward state metrics.

Use of double-ACS and use of the same hardware for both stages (through rising-edge and falling edge of the clock) of the turbo decoding process minimize the required hardware resources by minimizing the number of required multiplexers and simplifying the placement of the components. Further, since the computations are performed using modulo arithmetic, a normalization process can be eliminated from the double-ACS hardware.

As described above, a decoder uses mathematical and approximation techniques to reduce the time for computation and memory otherwise required in turbo decoding. In particular, the decoder uses modulo arithmetic in one or more modified maximum a posteriori (MAP) modules configured with double add-compare-select (ACS) circuits. The modified MAP module uses a parallel window technique to perform backward state metric calculation recursion and to store the metrics. Forward state metric calculation and extrinsic information calculation are performed in parallel using the stored backward state metrics. These techniques increase the speed of computation and reduce the memory required for computation.

The present invention has been described above in terms of exemplary embodiments so that an understanding of the present invention can be conveyed. Any embodiment described herein as “exemplary” is not necessarily to be construed as preferred or advantageous over other embodiments. Moreover, there are many configurations for a communication system using modified turbo decoding and/or multicarrier processing not specifically described herein but with which the present invention is applicable. The present invention should therefore not be seen as limited to the particular embodiments described herein, but rather, it should be understood that the present invention has wide applicability with respect to wireless communication systems generally. However, it should be understood that some aspects of the invention can be practiced in wired communication systems. All modifications, variations, or equivalent arrangements and implementations that are within the scope of the attached claims should therefore be considered within the scope of the invention.

Appendix

Functions for Modulo-Arithmetic Computation

#define METRIC_RANGE 2048 //11 bit registers (positive integers)
int modulo_sub(int x, int y)

| { | int output; |
|---|---|
| | output = x − y; |
| | if (output >= METRIC_RANGE) |
| | output = output − METRIC_RANGE; |
| | else if (output < 0) |
| | output = output + METRIC_RANGE; |
| | return(output); |

}
int modulo_add(int x, int y)

| { | int output; |
|---|---|
| | output = x + y; |
| | if (output >= METRIC_RANGE) |
| | output = output − METRIC_RANGE; |
| | else if (output < 0) |
| | output = output + METRIC_RANGE; |
| | return(output); |

}
int max_int(int x, int y)

| { | int output; |
|---|---|
| | if (modulo_sub(x, y) < METRIC_RANGE/2) |
| | output = x; |
| | else |
| | output = y; |
| | return(output); |

}

Calculation of Backward State Metric Recursion (Beta) Using Modulo-Arithmetic

```
#define R_LENGTH 128
#define P_LENGTH 30
// Compute beta: initialization
if ((i == num_windows-1) ∥ ((i == num_windows-2) &&
  (N_data − (num_windows-1)*R_LENGTH < P_LENGTH)))
{
    beta[(beta_window_sz-1)*8 + 0] = 508;
    beta[(beta_window_sz-1)*8 + 1] = 254;
    beta[(beta_window_sz-1)*8 + 2] = 127;
    beta[(beta_window_sz-1)*8 + 3] = 127;
    beta[(beta_window_sz-1)*8 + 4] = 0;
    beta[(beta_window_sz-1)*8 + 5] = 0;
    beta[(beta_window_sz-1)*8 + 6] = 127;
    beta[(beta_window_sz-1)*8 + 7] = 127;
}
else
{
    for (k=0; k<8; k++) beta[(beta_window_sz-1)*8 + k] = 0;
}
// Compute beta: computation
counter = i*R_LENGTH + num_bits + tp_length − 1;
for (k=beta_window_sz-2; k>=0; k−−)
{
    metric_t = modulo_sub(beta[(k+1)*8 + 0], metric11[counter]);
    metric_b = modulo_add(beta[(k+1)*8 + 4], metric11[counter]);
    beta[k*8 + 0] = max_int(metric_t, metric_b);
    metric_t = modulo_add(beta[(k+1)*8 + 0], metric11[counter]);
    metric_b = modulo_sub(beta[(k+1)*8 + 4], metric11[counter]);
    beta[k*8 + 1] = max_int(metric_t, metric_b);
    metric_t = modulo_add(beta[(k+1)*8 + 1], metric10[counter]);
    metric_b = modulo_sub(beta[(k+1)*8 + 5], metric10[counter]);
    beta[k*8 + 2] = max_int(metric_t, metric_b);
    metric_t = modulo_sub(beta[(k+1)*8 + 1], metric10[counter]);
    metric_b = modulo_add(beta[(k+1)*8 + 5], metric10[counter]);
    beta[k*8 + 3] = max_int(metric_t, metric_b);
    metric_t = modulo_sub(beta[(k+1)*8 + 2], metric10[counter]);
    metric_b = modulo_add(beta[(k+1)*8 + 6], metric10[counter]);
    beta[k*8 + 4] = max_int(metric_t, metric_b);
    metric_t = modulo_add(beta[(k+1)*8 + 2], metric10[counter]);
    metric_b = modulo_sub(beta[(k+1)*8 + 6], metric10[counter]);
    beta[k*8 + 5] = max_int(metric_t, metric_b);
    metric_t = modulo_add(beta[(k+1)*8 + 3], metric11[counter]);
    metric_b = modulo_sub(beta[(k+1)*8 + 7], metric11[counter]);
    beta[k*8 + 6] = max_int(metric_t, metric_b);
    metric_t = modulo_sub(beta[(k+1)*8 + 3], metric11[counter]);
    metric_b = modulo_add(beta[(k+1)*8 + 7], metric11[counter]);
    beta[k*8 + 7] = max_int(metric_t, metric_b);
    counter−−;
}
```

Calculation of Forward State Metric Recursion (Alpha) and Extrinsic Information Using Modulo-Arithmetic

| // Compute alpha: initialization | |
|---|---|
| alpha = alpha_array1; alpha_new = alpha_array2; | |
| if (i==0) | |
| { | alpha[0] = 508; alpha[1] = 0; |

alpha[2] = 127; alpha[3] = 127;
alpha[4] = 254; alpha[5] = 0;
alpha[6] = 127; alpha[7] = 127;

}
else
{

for (k=0; k<8; k++) alpha[k] = 0;

}
// Compute alpha: computation
counter = i*R_LENGTH − hp_length;
factor = 0;
for (k=0; k<hp_length+num_bits; k++)
{

metric_t = modulo_sub(alpha[0], metric11[counter]);
metric_b = modulo_add(alpha[1], metric11[counter]);
alpha_new[0] = max_int(metric_t, metric_b);
metric_t = modulo_add(alpha[0], metric11[counter]);
metric_b = modulo_sub(alpha[1], metric11[counter]);
alpha_new[4] = max_int(metric_t, metric_b);
metric_t = modulo_add(alpha[2], metric10[counter]);
metric_b = modulo_sub(alpha[3], metric10[counter]);
alpha_new[1] = max_int(metric_t, metric_b);
metric_t = modulo_sub(alpha[2], metric10[counter]);
metric_b = modulo_add(alpha[3], metric10[counter]);
alpha_new[5] = max_int(metric_t, metric_b);
metric_t = modulo_sub(alpha[4], metric10[counter]);
metric_b = modulo_add(alpha[5], metric10[counter]);
alpha_new[2] = max_int(metric_t, metric_b);
metric_t = modulo_add(alpha[4], metric10[counter]);
metric_b = modulo_sub(alpha[5], metric10[counter]);
alpha_new[6] = max_int(metric_t, metric_b);
metric_t = modulo_add(alpha[6], metric11[counter]);
metric_b = modulo_sub(alpha[7], metric11[counter]);
alpha_new[3] = max_int(metric_t, metric_b);
metric_t = modulo_sub(alpha[6], metric11[counter]);
metric_b = modulo_add(alpha[7], metric11[counter]);
alpha_new[7] = max_int(metric_t, metric_b);

// Compute extrinsic information

```
if (k >= hp_length)
{
    temp_deno = modulo_sub(modulo_add(alpha[0],
            beta[factor*8 + 0]), metric11[counter]);
    denominator = temp_deno;
    temp_num = modulo_add(modulo_add(alpha[0],
            beta[factor*8 + 4]), metric11[counter]);
    numerator = temp_num;
    temp_deno = modulo_sub(modulo_add(alpha[1],
            beta[factor*8 + 4]), metric11[counter]);
    denominator = max_int(temp_deno, denominator);
    temp_num = modulo_add(modulo_add(alpha[1],
            beta[factor*8 + 0]), metric11[counter]);
    numerator = max_int(temp_num, numerator);
    temp_deno = modulo_sub(modulo_add(alpha[2],
            beta[factor*8 + 5]), metric10[counter]);
    denominator = max_int(temp_deno, denominator);
    temp_num = modulo_add(modulo_add(alpha[2],
            beta[factor*8 + 1]), metric10[counter]);
    numerator = max_int(temp_num, numerator);
    temp_deno = modulo_sub(modulo_add(alpha[3],
            beta[factor*8 + 1]), metric10[counter]);
    denominator = max_int(temp_deno, denominator);
    temp_num = modulo_add(modulo_add(alpha[3],
            beta[factor*8 + 5]), metric10[counter]);
    numerator = max_int(temp_num, numerator);
    temp_deno = modulo_sub(modulo_add(alpha[4],
            beta[factor*8 + 2]), metric10[counter]);
    denominator = max_int(temp_deno, denominator);
    temp_num = modulo_add(modulo_add(alpha[4],
            beta[factor*8 + 6]), metric10[counter]);
    numerator = max_int(temp_num, numerator);
    temp_deno = modulo_sub(modulo_add(alpha[5],
            beta[factor*8 + 6]), metric10[counter]);
    denominator = max_int(temp_deno, denominator);
    temp_num = modulo_add(modulo_add(alpha[5],
            beta[factor*8 + 2]), metric10[counter]);
    numerator = max_int(temp_num, numerator);
    temp_deno = modulo_sub(modulo_add(alpha[6],
            beta[factor*8 + 7]), metric11[counter]);
    denominator = max_int(temp_deno, denominator);
    temp_num = modulo_add(modulo_add(alpha[6],
            beta[factor*8 + 3]), metric11[counter]);
    numerator = max_int(temp_num, numerator);
    temp_deno = modulo_sub(modulo_add(alpha[7],
            beta[factor*8 + 3]), metric11[counter]);
    denominator = max_int(temp_deno, denominator);
    temp_num = modulo_add(modulo_add(alpha[7],
            beta[factor*8 + 7]), metric11[counter]);
    numerator = max_int(temp_num, numerator);
    sequence1[counter] = modulo_sub(modulo_{—}
            sub(numerator, denominator),
            out_deinterleave2[counter]);
    if (sequence1[counter] >= METRIC_RANGE/2)
        sequence1[counter] = sequence1[counter] −
                    METRIC_RANGE;
    if (sequence1[counter] > 127)
        sequence1[counter] = 127;
    else if (sequence1[counter] < −127)
        sequence1[counter] = −127;
    factor++;
}
counter++;
temp = alpha; alpha = alpha_new; alpha_new = temp;
```

}

1. A decoder for a communication system, the decoder comprising:
a first decoder block that receives a soft-input information bit for decoding and calculates a probability estimate for the soft-input information bit;
a second decoder block configured to receive and process the probability estimate of the soft-input information bit using modulo arithmetic operations; and
a decision module adapted to receive the processed soft-input information bit and to generate hard-decision output information.

2. A decoder as defined in claim 1, wherein the first decoder block includes an output element configured to receive the soft-input information bit and to generate extrinsic information.

3. A decoder as defined in claim 2, further comprising:
an interleaver configured to interleave the received output extrinsic information, and to direct the interleaved output to the second decoder block.

4. A decoder as defined in claim 3, wherein the second decoder block includes a state metric calculator configured to calculate backward and forward metrics using the soft-input information bit and the extrinsic information.

5. A decoder as defined in claim 4, further comprising:
a deinterleaver configured to deinterleave output of the second decoder block, and to feed the deinterleaved output back to the first decoder block.

6. A decoder for a communication system, the decoder comprising:
an iterative decoding module configured to receive soft-input information bits, the iterative decoding module iterating on probability estimates of the soft-input information bits to generate soft-decision output information, wherein the iterative decoding module generates and processes both backward and forward metrics substantially simultaneously using modulo arithmetic operations; and
an output module configured to receive the soft-decision output information and to generate hard-decision output information.

7. A decoder as defined in claim 6, wherein the iterative decoding module includes two sub-modules to simultaneously process first and second stages of trellis decoding.

8. A decoder as defined in claim 7, wherein the iterative decoding module includes an output element configured to receive the soft-input information bits and output extrinsic information on the first and second stage of trellis decoding.

9. A decoder as defined in claim 8, further comprising:
an interleaver configured to interleave the received output extrinsic information, and to direct the interleaved output to the iterative decoding module for the second stage of trellis decoding.

10. A decoder as defined in claim 8, further comprising:
a deinterleaver configured to deinterleave the received output extrinsic information, and to direct the deinterleaved output to the iterative decoding module for the first stage of trellis decoding.

11. A module as defined in claim 6, wherein the iterative decoding module is a maximum a priori (MAP) decoder.

12. A receiver for a communication system, comprising:
an RF unit configured to receive RF signals and to down-convert the signal to a baseband signal;
a demodulator configured to demodulate, process, and digitize the baseband signal into soft-input information bits; and
an iterative decoding module configured to receive the soft-input information bits, the iterative decoding module iterating on probability estimates of the soft-input information bits to generate hard-decision output information, wherein the iterative decoding module includes a plurality of arithmetic modules operating to generate and process both backward and forward metrics substantially simultaneously using modulo arithmetic operations.

13. A receiver as defined in claim 12, wherein the demodulator includes a demapper for converting the digitized data into the soft-input information bits.

14. A receiver as defined in claim 12, wherein the demodulator is a multicarrier demodulator.

15. A receiver as defined in claim 14, wherein the multicarrier demodulator includes a fast Fourier transform module to calculate Fourier transforms of the baseband signals.

16. A receiver as defined in claim 12, wherein the plurality of arithmetic modules includes two sub-modules to simultaneously process first and second stages of trellis decoding.

17. A soft-input soft-output (SISO) decoding block for a communication system, the block comprising:
a first plurality of modules configured to receive soft-input backward state metrics, the first plurality of modules operating to process the backward state metrics using modulo arithmetic;
a first multiplexer to select the backward state metrics;
a second plurality of modules configured to receive soft-input forward state metrics, the second plurality of modules operating to process the forward state metrics using modulo arithmetic; and
a second multiplexer to select the forward state metrics.

18. A block as defined in claim 17, wherein the SISO block is a maximum a priori (MAP) decoder.

19. A block as defined in claim 17, wherein the first plurality of modules includes a first modulo arithmetic comparator to provide a selection signal to the first multiplexer.

20. A block as defined in claim 17, wherein the second plurality of modules includes a second modulo arithmetic comparator to provide a selection signal to the second multiplexer.

21. A block as defined in claim 17, further comprising:
a third multiplexer configured to provide an appropriate branch metrics for the first and second plurality of modules.

22. A block as defined in claim 21, further comprising:
an input clock configured to synchronize and control processing of the backward and forward state metrics.

23. A block as defined in claim 21, wherein the third multiplexer includes a first signal element to enable the first plurality of modules at rising edges of the input clock.

24. A block as defined in claim 22, wherein the third multiplexer includes a second signal element to enable the second plurality of modules at falling edges of the input clock.

25. A method of decoding soft-input symbol block data in a communication system, comprising:
performing backward recursion of a trellis diagram by computing backward state metrics of each node on the trellis diagram of the symbol block data;
storing the backward state metrics to a storage mechanism;
performing forward recursion of the trellis diagram by computing forward state metrics of each node on the trellis diagram of the symbol block data; and
calculating extrinsic information.

26. A method as defined in claim 25, further comprising:
computing first and second branch metrics along branches from two previous nodes of the trellis diagram.

27. A method as defined in claim 26, wherein performing backward recursion on a trellis diagram includes computing a sum comprising a previous backward state metric multiplied by a first branch metric and a previous backward state metric multiplied by a second branch metric.

28. A method as defined in claim 26, wherein calculating extrinsic information includes computing a log likelihood ratio for each time point of the trellis diagram.

29. A method as defined in claim 26, wherein computing a log likelihood ratio includes:
detecting when a decoded bit is determined to be a ‘1’; and
computing a first sum of a plurality of products of the backward state metrics, forward state metrics, and the first and second branch metrics at a particular time that is associated with a decoded bit representation ‘1’.

30. A method as defined in claim 29, wherein computing a log likelihood ratio includes:
detecting when a decoded bit is determined to be a ‘0’; and
computing a second sum of a plurality of products of the backward state metrics, forward state metrics, and the first and second branch metrics at a particular time that is associated with a decoded bit representation ‘0’.

31. A method as defined in claim 30, wherein computing a log likelihood ratio includes dividing the first sum by the second sum.

32. A method as defined in claim 31, wherein calculating extrinsic information includes subtracting a probability estimate of the soft-input symbol block data from the log likelihood ratio.

33. A method as defined in claim 32, further comprising:
iterating on performing backward recursion, storing, performing forward recursion, and calculating extrinsic information.

34. A method as defined in claim 33, further comprising:
retrieving decoded information bits from the iterating by examining a sign bit of the log likelihood ratio.

35. A method as defined in claim 34, further comprising:
outputting a hard-decision bit as a ‘1’ if the sign bit is positive; and
outputting a hard-decision bit as a ‘0’ if the sign bit is negative.

36. A method as defined in claim 25, further comprising:
dividing the symbol block data into a plurality of windows, each window including soft-input bits.

37. A method as defined in claim 36, wherein dividing the symbol block data includes allowing overlaps between the plurality of windows.

38. A method as defined in claim 36, further comprising:
processing the soft-input bits of the plurality of windows in parallel.

39. A method as defined in claim 38, further comprising:
interleaving the soft-input bits in the plurality of windows.
